(19) United States
(12) Patent Application Publication
(10) Pub. No.: US 2019/0106621 A1
(43) Pub. Date: Apr. 11, 2019

(54) LUMINESCENT GLASS-CERAMIC MATERIAL, METHOD FOR MANUFACTURING THE SAME, AND LIGHT EMITTING DEVICE INCLUDING THE SAME

(71) Applicant: Chung Yuan Christian University, Taoyuan City (TW)

(72) Inventors: Wei-Jen Liu, Taoyuan City (TW); Jy-Chern Chang, Taoyuan City (TW)

(73) Assignee: Chung Yuan Christian University, Taoyuan City (TW)

(21) Appl. No.: 15/880,508

(22) Filed: Jan. 25, 2018

(30) Foreign Application Priority Data
Oct. 5, 2017 (TW) 106134425

(51) Int. Cl. C09K 11/02; H01L 33/50; C09K 11/58; C03C 3/066

(52) U.S. Cl. CPC C09K 11/02; C03C 3/066; C09K 11/584; H01L 33/502

(57) ABSTRACT

A luminescent glass-ceramic material, its manufacturing method, and a light emitting device including the luminescent glass-ceramic material are provided. The luminescent glass-ceramic material includes a glass material and phosphors, wherein the glass material includes SiO₂, Al₂O₃, Na₂O, K₂O, CaO, and B₂O₃.

### CROSS-REFERENCE TO RELATED APPLICATION

This application claims the priority benefit of Taiwan application no. 106134425, filed on Oct. 5, 2017. The entirety of the above-mentioned patent application is hereby incorporated by reference herein and made a part of this specification.

### BACKGROUND OF THE INVENTION

### Field of the Invention

The invention relates to a glass-ceramic material, its manufacturing method, and a light emitting device, and in particular, to a luminescent glass-ceramic material, its manufacturing method, and a light emitting device.

### Description of Related Art

In addition to exhibiting advantages including low power consumption, a small size, high luminance, and a long lifetime, the light emitting diode (LED) is also a green light source that is in line with ecological and energy-saving concepts. Generally, light emitting devices including light emitting diodes are mostly packaged with a packaging material formed by synthesizing phosphors and a resin. However, such packaging material is subjected to issues such as degradation and yellowing after long-time use, which reduces the light emitting efficiency of the light emitting device.

### SUMMARY OF THE INVENTION

The invention provides a luminescent glass-ceramic material, its manufacturing method, and a light emitting device including the luminescent glass-ceramic material that prevent issues such as degradation and yellowing caused by conventional packaging materials and further improve a light emitting efficiency of the light emitting device.

The invention provides a luminescent glass-ceramic material including a glass material and phosphors. The glass material includes SiO₂, Al₂O₃, Na₂O, K₂O, CaO, and B₂O₃.

In an embodiment of the invention, in the luminescent glass-ceramic material, the glass material may be 90 wt % to 99 wt % and the phosphors may be 1 wt % to 10 wt % based on a total weight of the glass material and the phosphors.

In an embodiment of the invention, in the luminescent glass-ceramic material, the glass material may include 67.2 wt % to 82.1 wt % SiO₂, 6.5 wt % to 8 wt % Al₂O₃, 5.5 wt % to 6.7 wt % Na₂O, 1.7 wt % to 2.1 wt % K₂O, 0.7 wt % to 0.9 wt % CaO, and 8.4 wt % to 10.3 wt % B₂O₃.

In an embodiment of the invention, in the luminescent glass-ceramic material, the phosphors may include (Y,Lu,Gd)₃(Al,Ga)₅O₁₂:Ce³⁺, (Ca,Sr,Ba)₂Si₅N₈:Eu²⁺, (Sr,Ca)AlSiN₃:Eu²⁺, α-SiAlON:Eu²⁺, β-SiAlON:Eu²⁺, (Ca,Sr,Ba)₂SiO₄:Eu²⁺, (Ca,Sr,Ba)Si₂O₂N₂:Eu²⁺, or K₂(Si,Ti)F₆:Mn⁴⁺.

The invention provides a manufacturing method of a luminescent glass-ceramic material including the following steps: performing a mixing process on a glass material and phosphors to form a mixture, wherein the glass material includes SiO₂, Al₂O₃, Na₂O, K₂O, CaO, and B₂O₃; performing a sintering process on the mixture; and performing a cooling process on the mixture that has undergone the sintering process to obtain a luminescent glass-ceramic material.

According to an embodiment of the invention, in the manufacturing method of a luminescent glass-ceramic material, the glass material may include 67.2 wt % to 82.1 wt % SiO₂, 6.5 wt % to 8 wt % Al₂O₃, 5.5 wt % to 6.7 wt % Na₂O, 1.7 wt % to 2.1 wt % K₂O, 0.7 wt % to 0.9 wt % CaO, and 8.4 wt % to 10.3 wt % B₂O₃.

According to an embodiment of the invention, in the manufacturing method of a luminescent glass-ceramic material, the phosphors may include (Y,Lu,Gd)₃(Al,Ga)₅O₁₂:Ce³⁺, (Ca,Sr,Ba)₂Si₅N:Eu²⁺, (Sr,Ca)AlSiN₃:Eu²⁺, α-SiAlON:Eu²⁺, β-SiAlON:Eu²⁺, (Ca,Sr,Ba)₂SiO₄:Eu²⁺, (Ca,Sr,Ba)Si₂O₂N₂:Eu²⁺, or K₂(Si,Ti)F₆:Mn⁴⁺.

According to an embodiment of the invention, in the manufacturing method of a luminescent glass-ceramic material, 90 wt % to 99 wt % of the glass material and 1 wt % to 10 wt % of the phosphors are mixed, for example, based on a total weight of the glass material and the phosphors in the mixing process.

According to an embodiment of the invention, in the manufacturing method of a luminescent glass-ceramic material, a sintering temperature for performing the sintering process may be 800° C. to 1200° C.

According to an embodiment of the invention, in the manufacturing method of a luminescent glass-ceramic material, the cooling process includes adopting a natural cooling method, for example.

According to an embodiment of the invention, the manufacturing method of a luminescent glass-ceramic material may further include carrying the mixture with a carrier after the mixing process and before the sintering process.

According to an embodiment of the invention, in the manufacturing method of a luminescent glass-ceramic material, the carrier is a quartz wool sheet, for example.

According to an embodiment of the invention, the manufacturing method of a luminescent glass-ceramic material may further include separating the luminescent glass-ceramic material from the carrier after the cooling process.

According to an embodiment of the invention, the manufacturing method of a luminescent glass-ceramic material may further include cutting the luminescent glass-ceramic material into a sheet shape.

According to an embodiment of the invention, in the manufacturing method of a luminescent glass-ceramic material, a thickness of the sheet-shaped luminescent glass-ceramic material may be 0.01 mm to 10 mm.

The invention provides a light emitting device including a light emitting diode and the foregoing luminescent glass-ceramic material. The luminescent glass-ceramic material covers the light emitting diode.

According to an embodiment of the invention, in the light emitting device, a wavelength of the light emitting diode may be 254 nm to 480 nm.

According to an embodiment of the invention, in the light emitting device, a shape of the luminescent glass-ceramic material may be a sheet shape.

In light of the above, in the luminescent glass-ceramic material and its manufacturing method provided in the invention, since the luminescent glass-ceramic material includes the glass material and the phosphors, and the glass material includes SiO₂, Al₂O₃, Na₂O, K₂O, CaO, and B₂O₃, the luminescent glass-ceramic material exhibits high thermal stability, high heat dissipation, and high transmittancy and can further prevent issues, such as degradation and yellowing, caused by conventional packaging materials. Moreover, since the light emitting device provided in the invention covers the light emitting diode with the luminescent glass-ceramic material, the light emitting device can exhibit a better light emitting efficiency.

To provide a further understanding of the aforementioned and other features and advantages of the disclosure, exemplary embodiments, together with the reference drawings, are described in detail below.

### BRIEF DESCRIPTION OF THE DRAWINGS

FIG. 1 is a schematic diagram illustrating a luminescent glass-ceramic material according to an embodiment of the invention.

FIG. 2 is a flowchart illustrating a manufacturing method of a luminescent glass-ceramic material according to an embodiment of the invention.

FIG. 3 is a schematic diagram illustrating a light emitting device according to an embodiment of the invention.

FIG. 4 illustrates a photoluminescence spectrum of a luminescent glass-ceramic material manufactured in experimental example 1.

FIG. 5 illustrates variable-temperature spectra of the luminescent glass-ceramic material manufactured in experimental example 1.

FIG. 6 illustrates normalized variable-temperature spectra of the luminescent glass-ceramic material manufactured in experimental example 1 and the general commercial phosphors YAG:Ce³⁺.

FIG. 7 illustrates constant-current electroluminescence spectra of light emitting devices manufactured in experimental examples 2 to 4.

FIG. 8 illustrates constant-current electroluminescence spectra of light emitting devices manufactured in experimental examples 5 to 7.

FIG. 9 illustrates variable-current electroluminescence spectra of the light emitting device manufactured in experimental example 3.

FIG. 10 illustrates variable-current electroluminescence spectra of the light emitting device manufactured in experimental example 6.

### DESCRIPTION OF THE EMBODIMENTS

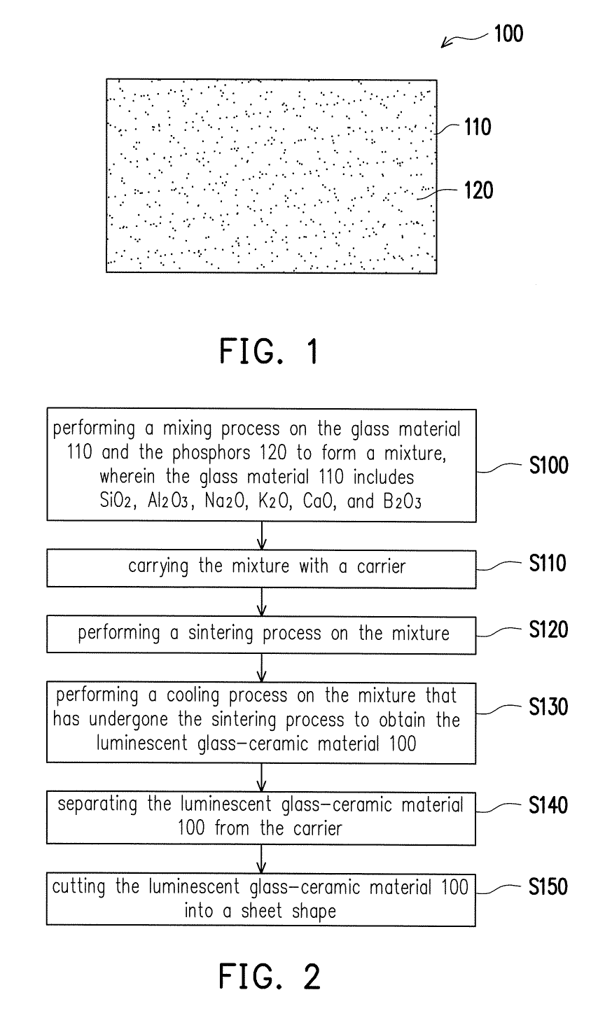

FIG. 1 is a schematic diagram illustrating a luminescent glass-ceramic material according to an embodiment of the invention.

Referring to FIG. 1, a luminescent glass-ceramic material 100 includes a glass material 110 and phosphors 120. The luminescent glass-ceramic material 100 may be in a sheet shape. Based on a total weight of the glass material 110 and the phosphors 120, the glass material 110 may be 90 wt % to 99 wt %, and the phosphors 120 may be 1 wt % to 10 wt %.

The glass material 110 includes SiO₂, Al₂O₃, Na₂O, K₂O, CaO, and B₂O₃ (also referred to as SiO₂—Al₂O₃—Na₂O—K₂O—CaO—B₂O₃). The glass material may include 67.2 wt % to 82.1 wt % SiO₂, 6.5 wt % to 8 wt % Al₂O₃, 5.5 wt % to 6.7 wt % Na₂O, 1.7 wt % to 2.1 wt % K₂O, 0.7 wt % to 0.9 wt % CaO, and 8.4 wt % to 10.3 wt % B₂O₃.

Moreover, the phosphors 120 may include (Y,Lu,Gd)₃(Al,Ga)₅O₁₂:Ce³⁺, (Ca,Sr,Ba)₂Si₅N₈:Eu²⁺, (Sr,Ca)AlSiN₃:Eu²⁺, α-SiAlON:Eu²⁺, β-SiAlON:Eu²⁺, (Ca,Sr,Ba)₂SiO₄:Eu²⁺, (Ca,Sr,Ba)Si₂O₂N₂:Eu²⁺, or K₂(Si,Ti)F₆:Mn⁴⁺.

In light of the foregoing embodiment, since the luminescent glass-ceramic material 100 includes the glass material 110 and the phosphors 120, and the glass material 110 includes SiO₂, Al₂O₃, Na₂O, K₂O, CaO, and B₂O₃, the luminescent glass-ceramic material 100 exhibits high thermal stability, high heat dissipation, and high transmittancy and can further prevent issues, such as degradation and yellowing, caused by conventional packaging materials. Moreover, the luminescent glass-ceramic material 100 is applicable to packaging of light emitting devices such as LED and exhibits excellent optical performance in optical testing, such that a light emitting device including the luminescent glass-ceramic material 100 is applicable to high power illumination and various screen displays.

FIG. 2 is a flowchart illustrating a manufacturing method of a luminescent glass-ceramic material according to an embodiment of the invention.

The manufacturing method of a luminescent glass-ceramic material of the present embodiment is described as being used to manufacture the luminescent glass-ceramic material 100 of FIG. 1, but the invention is not limited hereto. Reference may be made to the description in the foregoing embodiment for a detailed description of the components of the luminescent glass-ceramic material 100, which shall not be repeated here.

Referring to FIG. 1 and FIG. 2, in step S100, a mixing process is performed on the glass material 110 and the phosphors 120 to form a mixture, wherein the glass material 110 includes SiO₂, Al₂O₃, Na₂O, K₂O, CaO, and B₂O₃. For example, in the mixing process, based on a total weight of the glass material 110 and the phosphors 120, 90 wt % to 99 wt % of the glass material 110 and 1 wt % to 10 wt % of the phosphors 120 may be mixed.

The glass material 110 in the mixture may include 67.2 wt % to 82.1 wt % SiO₂, 6.5 wt % to 8 wt % Al₂O₃, 5.5 wt % to 6.7 wt % Na₂O, 1.7 wt % to 2.1 wt % K₂O, 0.7 wt % to 0.9 wt % CaO, and 8.4 wt % to 10.3 wt % B₂O₃.

Moreover, the phosphors 120 in the mixture may include (Y,Lu,Gd)₃(Al,Ga)₅O₁₂:Ce³⁺, (Ca,Sr,Ba)₂Si₅N₈:Eu²⁺, (Sr,Ca)AlSiN₃:Eu²⁺, α-SiAlON:Eu²⁺, β-SiAlON:Eu²⁺, (Ca,Sr,Ba)₂SiO₄:Eu²⁺, (Ca,Sr,Ba)Si₂O₂N₂:Eu²⁺, or K₂(Si,Ti)F₆:Mn⁴⁺.

Step S110 may be selectively performed to carry the mixture with a carrier. The carrier is, for example, a quartz wool sheet.

In step S120, a sintering process is performed on the mixture. A sintering temperature for performing the sintering process may be 800° C. to 1200° C., and may be 900° C., for example. For example, the sintering process may include the following steps. First, the mixture is placed into a high temperature furnace and is then heated in air atmosphere at a heating rate of 5° C./minute, and when the temperature rises to 300° C. and 600°, the temperature is respectively maintained for 30 minutes. Lastly, when it is heated to 900° C. at the heating rate of 5° C./minute, the temperature is maintained for 4 hours.

In step S130, a cooling process is performed on the mixture that has undergone the sintering process to obtain the luminescent glass-ceramic material 100. The cooling process involves, for example, cooling the mixture that has undergone the sintering process to room temperature by adopting a natural cooling method. In this embodiment, the obtained luminescent glass-ceramic material 100 may be in a block shape.

Step S140 may be selectively performed to separate the luminescent glass-ceramic material 100 from the carrier.

Step S150 may be selectively performed to cut the luminescent glass-ceramic material 100 into a sheet shape. Specifically, a thickness of the sheet-shaped luminescent glass-ceramic material is, for example, 0.01 mm to 10 mm.

In light of the foregoing embodiment, the luminescent glass-ceramic material 100 manufactured by the manufacturing method of the luminescent glass-ceramic material 100 exhibits high thermal stability, high heat dissipation, and high transmittancy and can further prevent issues, such as degradation and yellowing, caused by conventional packaging materials. Moreover, the luminescent glass-ceramic material 100 is applicable to packaging of light emitting devices such as LED and exhibits excellent optical performance in optical testing, such that a light emitting device including the luminescent glass-ceramic material 100 is applicable to high power illumination and various screen displays.

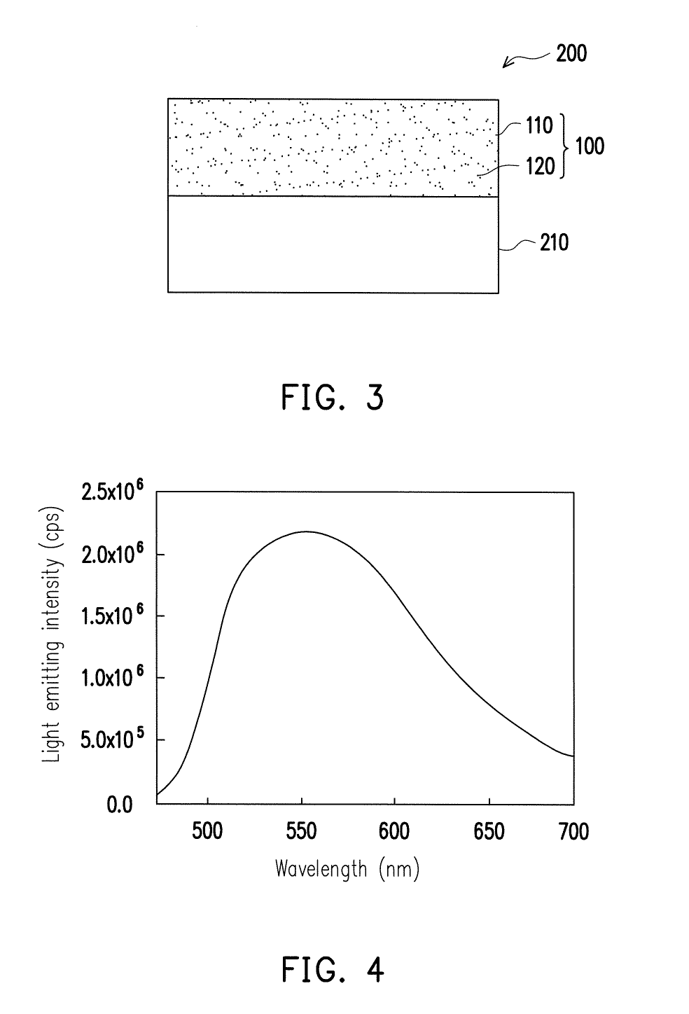

FIG. 3 is a schematic diagram illustrating a light emitting device according to an embodiment of the invention.

In the text below, an embodiment where the luminescent glass-ceramic material 100 of FIG. 1 is applied to a light emitting device is described with reference to FIG. 3. Moreover, the same components in FIG. 3 and FIG. 1 are labeled by the same numerals and are not repeatedly described.

Referring to FIG. 3, a light emitting device 200 includes a light emitting diode 210 and the luminescent glass-ceramic material 100, wherein the luminescent glass-ceramic material 100 covers the light emitting diode 210. A wavelength of the light emitting diode may be 254 nm to 480 nm.

In light of the foregoing embodiment, since the light emitting device 200 uses the luminescent glass-ceramic material 100 as a packaging material, it can prevent issues, such as degradation and yellowing, caused by conventional packaging materials and can exhibit excellent optical performance. Therefore, the light emitting device 200 is applicable to high power illumination and various screen displays.

In the text below, experimental examples are provided to verify the effect of the foregoing embodiments, but the scope of the invention is not limited to the description below.

### EXPERIMENTAL EXAMPLES

### Manufacturing Method of Luminescent Glass-Ceramic Materials of Experimental Example 1 to Experimental Example 7

First, according to the types and weights of the glass material and the phosphors listed in Table 1 below, the mixing process is formed on the glass material and the phosphors to form a mixture. The glass material is SiO₂—Al₂O₃—Na₂O—K₂O—CaO—B₂O₃, wherein the glass material includes 74.64 wt % SiO₂, 7.27 wt % Al₂O₃, 6.06 wt % Na₂O, 1.91 wt % K₂O, 0.79 wt % CaO, and 9.32% B₂O₃.

TABLE 1

| | | | | | Thickness of |
|---|---|---|---|---|---|
| | | | | | sheet-shaped |
| | Glass material | | Phosphors | | luminescent |
| Experimental | | Weight | | Weight | glass-ceramic |
| example | Type | (gram) | Type | (gram) | material (mm) |
| 1 | SiO₂—Al₂O₃—Na₂O—K₂O—CaO—B₂O₃ | 9 | YAG:Ce³⁺ | 1 | 0.5 |
| 2 | | | (Y₃Al₅O₁₂:Ce³⁺) | | 0.2 |
| 3 | | | | | 0.4 |
| 4 | | | | | 0.6 |
| 5 | | | LuAG:Ce³⁺ | | 0.2 |
| 6 | | | (Lu₃Al₅O₁₂:Ce³⁺) | | 0.4 |
| 7 | | | | | 0.6 |

Next, quartz wool sheets are used to respectively carry the mixtures of experimental example 1 to experimental example 7. Then, the mixtures are placed into a high temperature furnace to perform the sintering process, wherein the sintering process includes the following steps. Heating is performed in air atmosphere at a heating rate of 5° C./minute, and when the temperature rises to 300° C. and 600°, the temperature is respectively maintained for 30 minutes. Lastly, when it is heated to 900° C. at the heating rate of 5° C./minute, the temperature is maintained for 4 hours.

Afterwards, the cooling process is performed on the mixtures that have undergone the sintering process in experimental example 1 to experimental example 7 based on a natural cooling method to cool the temperature to room temperature and form block-shaped luminescent glass-ceramic materials. Then, the quartz wool sheets and the block-shaped luminescent glass-ceramic materials are separated. Further, the block-shaped luminescent glass-ceramic materials are cut into a sheet shape, wherein thicknesses of the luminescent glass-ceramic sheets manufactured in experimental example 1 to experimental example 7 are as indicated in Table 1.

<Photoluminescence Spectroscopy>

FIG. 4 illustrates a photoluminescence spectrum of the luminescent glass-ceramic material manufactured in experimental example 1.

A photoluminescence spectroscopy is performed on the luminescent glass-ceramic material manufactured in experimental example 1, and the result is as shown in FIG. 4. The photoluminescence spectrum of the luminescent glass-ceramic material of experimental example 1 is largely identical to the photoluminescence spectrum of the general commercial phosphors YAG:Ce³⁺.

<Variable-Temperature Spectroscopy>

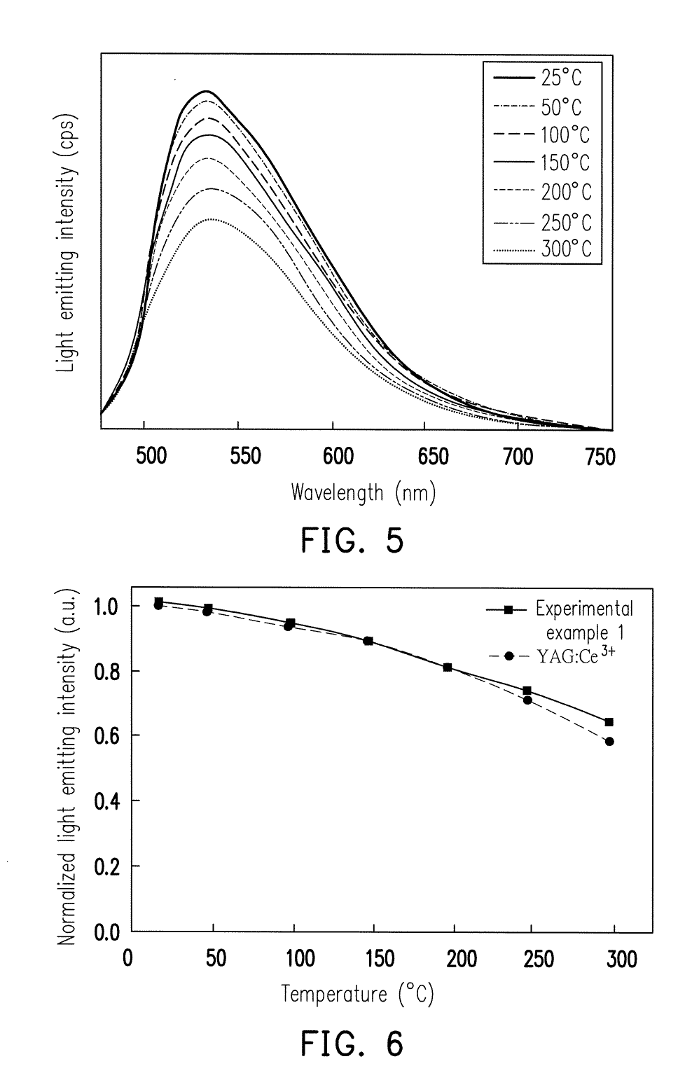

FIG. 5 illustrates variable-temperature spectra of the luminescent glass-ceramic material manufactured in experimental example 1. FIG. 6 illustrates normalized variable-temperature spectra of the luminescent glass-ceramic material manufactured in experimental example 1 and the general commercial phosphors YAG:Ce³⁺.

A variable-temperature spectroscopy is performed respectively on the luminescent glass-ceramic sheet manufactured in experimental example 1 and the phosphors YAG:Ce³⁺.

According to the results of FIG. 5, temperature variations have slight effect on a wavelength value of the luminescent glass-ceramic sheet manufactured in experimental example 1 at the peak, which means that the luminescent glass-ceramic sheet exhibits high thermal stability.

FIG. 6 illustrates normalized variable-temperature spectra of the luminescent glass-ceramic sheet manufactured in experimental example 1 and the general commercial phosphors YAG:Ce³⁺. According to the results of FIG. 6, at the same temperature, a normalized light emitting intensity of the luminescent glass-ceramic sheet of experimental example 1 is greater, which means that the luminescent glass-ceramic sheet exhibits high heat dissipation.

### Manufacturing Method of Light Emitting Devices of Experimental Example 2 to Experimental Example 7

The luminescent glass-ceramic sheets of experimental examples 2 to 7 above are respectively covered on light emitting diodes of the same type to manufacture 6 light emitting devices, wherein a wavelength of light emitted by the light emitting diode is 450 nm to 460 nm.

<Constant-Current Electroluminescence Spectroscopy>

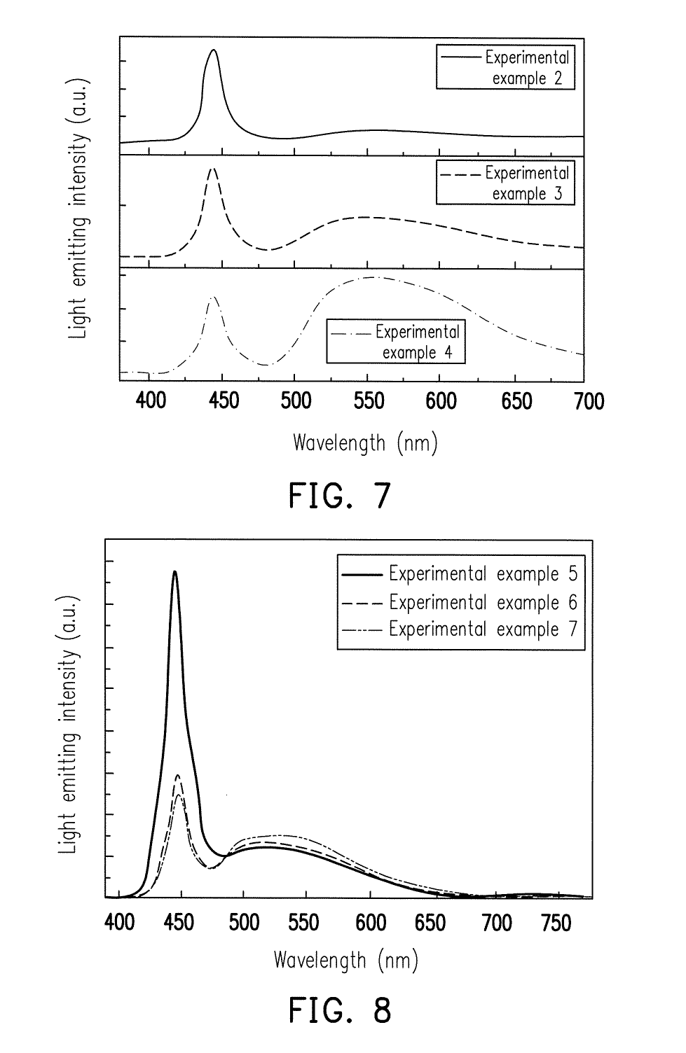

FIG. 7 illustrates constant-current electroluminescence spectra of the light emitting devices manufactured in experimental examples 2 to 4. FIG. 8 illustrates constant-current electroluminescence spectra of the light emitting devices manufactured in experimental examples 5 to 7.

A constant-current electroluminescence spectroscopy is performed respectively on the light emitting devices of experimental examples 2 to 4, and the results are as shown in FIG. 7. Moreover, a constant-current electroluminescence spectroscopy is performed respectively on the light emitting devices of experimental examples 5 to 7, and the results are as shown in FIG. 8. Specifically, in FIG. 7 and FIG. 8, the left half shows the spectrum of the light emitting diode, and the right half shows the spectrum of the luminescent glass-ceramic sheet. In addition, according to FIG. 7 and FIG. 8, when the thickness of the luminescent glass-ceramic sheet is increased, the light emitting intensity of the light emitting diode is decreased, and the light emitting intensity of the luminescent glass-ceramic sheet is relatively higher. Therefore, by adjusting the thickness of the luminescent glass-ceramic sheet, the luminous color of the light emitting device can be changed.

<CIE Chromaticity Analysis>

A CIE (International Commission on Illumination) chromaticity analysis is performed on the light emitting devices of experimental examples 2 to 7, and the results are as shown in Table 2.

TABLE 2

| | |
|---|---|
| | CIE |
| | chromaticity |
| Experimental | coordinate |

| example | x | y |
|---|---|---|
| 2 | 0.25 | 0.20 |
| 3 | 0.33 | 0.35 |
| 4 | 0.39 | 0.44 |
| 5 | 0.21 | 0.19 |
| 6 | 0.26 | 0.32 |
| 7 | 0.27 | 0.35 |

According to Table 2, by adjusting the thickness of the luminescent glass-ceramic sheet manufactured in experimental examples 2 to 7, the luminous color of the light emitting devices can be changed.

<Variable-Current Electroluminescence Spectroscopy>

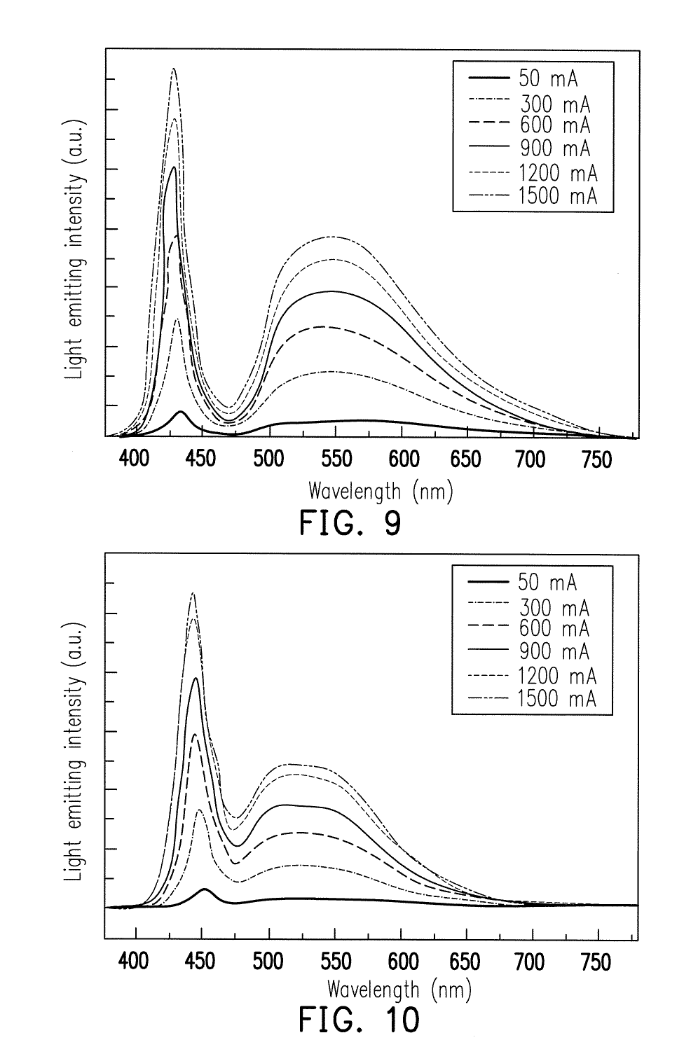

FIG. 9 illustrates variable-current electroluminescence spectra of the light emitting device manufactured in experimental example 3. FIG. 10 illustrates variable-current electroluminescence spectra of the light emitting device manufactured in experimental example 6.

A variable-current electroluminescence spectroscopy is performed on the light emitting devices manufactured in experimental example 3 and experimental example 6, and the results are respectively as shown in FIG. 9 and FIG. 10. In FIG. 9 and FIG. 10, the left half shows the spectrum of the light emitting diode, and the right half shows the spectrum of the luminescent glass-ceramic sheet. Moreover, according to the results of FIG. 9 and FIG. 10, current variations have slight effect on a wavelength value of the luminescent glass-ceramic sheets manufactured in experimental example 3 and experimental example 6 and the light emitting diode at the peak, which means that current variations have slight effect on the luminous color of the light emitting devices of experimental example 3 and experimental example 6.

<Light Emitting Efficiency Testing>

A light emitting efficiency testing is performed on the light emitting devices manufactured in experimental examples 2 to 7, and the results are as shown in Table 3.

TABLE 3

| Experimental | Light emitting |
|---|---|
| example | efficiency (lm/W) |
| 2 | 61.7 |
| 3 | 57.6 |
| 4 | 48.8 |
| 5 | 62.8 |
| 6 | 78.2 |
| 7 | 73.5 |

According to Table 3, the light emitting devices manufactured in experimental examples 2 to 7 exhibit high light emitting efficiencies.

In summary of the above, in the luminescent glass-ceramic material, its manufacturing method, and the light emitting device including the luminescent glass-ceramic material of the embodiments, due to the specific composition of the glass material in the luminescent glass-ceramic material, issues such as degradation and yellowing caused by conventional packaging materials can be prevented, and the light emitting efficiency of the light emitting device can further be improved.

Although the invention is disclosed as the embodiments above, the embodiments are not meant to limit the invention. Any person skilled in the art may make slight modifications and variations without departing from the spirit and scope of the invention. Therefore, the protection scope of the invention shall be defined by the claims attached below.

1. A luminescent glass-ceramic material comprising:
a glass material comprising SiO₂, Al₂O₃, Na₂O, K₂O, CaO, and B₂O₃; and
phosphors.

2. The luminescent glass-ceramic material according to claim 1, wherein the glass material is 90 wt % to 99 wt % and the phosphors are 1 wt % to 10 wt % based on a total weight of the glass material and the phosphors.

3. The luminescent glass-ceramic material according to claim 1, wherein the glass material comprises 67.2 wt % to 82.1 wt % SiO₂, 6.5 wt % to 8 wt % Al₂O₃, 5.5 wt % to 6.7 wt % Na₂O, 1.7 wt % to 2.1 wt % K₂O, 0.7 wt % to 0.9 wt % CaO, and 8.4 wt % to 10.3 wt % B₂O₃.

4. The luminescent glass-ceramic material according to claim 1, wherein the phosphors comprise (Y,Lu,Gd)₃(Al,Ga)₅O₁₂:Ce³⁺, (Ca,Sr,Ba)₂Si₅N₈:Eu²⁺, (Sr,Ca)AlSiN₃:Eu²⁺, α-SiAlON:Eu²⁺, β-SiAlON:Eu²⁺, (Ca,Sr,Ba)₂SiO₄:Eu²⁺, (Ca,Sr,Ba)Si₂O₂N₂:Eu²⁺, or K₂(Si,Ti)F₆:Mn⁴⁺.

5. A manufacturing method of a luminescent glass-ceramic material, comprising:
performing a mixing process on a glass material and phosphors to form a mixture, wherein the glass material comprises SiO₂, Al₂O₃, Na₂O, K₂O, CaO, and B₂O₃;
performing a sintering process on the mixture; and
performing a cooling process on the mixture that has undergone the sintering process to obtain a luminescent glass-ceramic material.

6. The manufacturing method of a luminescent glass-ceramic material according to claim 5, wherein the glass material comprises 67.2 wt % to 82.1 wt % SiO₂, 6.5 wt % to 8 wt % Al₂O₃, 5.5 wt % to 6.7 wt % Na₂O, 1.7 wt % to 2.1 wt % K₂O, 0.7 wt % to 0.9 wt % CaO, and 8.4 wt % to 10.3 wt % B₂O₃.

7. The manufacturing method of a luminescent glass-ceramic material according to claim 5, wherein the phosphors comprise (Y,Lu,Gd)₃(Al,Ga)₅O₁₂:Ce³⁺, (Ca,Sr,Ba)₂Si₅N₈:Eu²⁺, (Sr,Ca)AlSiN₃:Eu²⁺, α-SiAlON:Eu²⁺, β-SiAlON:Eu²⁺, (Ca,Sr,Ba)₂SiO₄:Eu²⁺, (Ca,Sr,Ba)Si₂O₂N₂:Eu²⁺, or K₂(Si,Ti)F₆:Mn⁴⁺.

8. The manufacturing method of a luminescent glass-ceramic material according to claim 5, wherein 90 wt % to 99 wt % of the glass material and 1 wt % to 10 wt % of the phosphors are mixed based on a total weight of the glass material and the phosphors in the mixing process.

9. The manufacturing method of a luminescent glass-ceramic material according to claim 5, wherein a sintering temperature for performing the sintering process is 800° C. to 1200° C.

10. The manufacturing method of a luminescent glass-ceramic material according to claim 5, wherein the cooling process comprises adopting a natural cooling method.

11. The manufacturing method of a luminescent glass-ceramic material according to claim 5, further comprising carrying the mixture with a carrier after the mixing process and before the sintering process.

12. The manufacturing method of a luminescent glass-ceramic material according to claim 11, wherein the carrier comprises a quartz wool sheet.

13. The manufacturing method of a luminescent glass-ceramic material according to claim 11, further comprising separating the luminescent glass-ceramic material from the carrier after the cooling process.

14. The manufacturing method of a luminescent glass-ceramic material according to claim 5, further comprising cutting the luminescent glass-ceramic material into a sheet shape.

15. The manufacturing method of a luminescent glass-ceramic material according to claim 14, wherein a thickness of the sheet-shaped luminescent glass-ceramic material is 0.01 mm to 10 mm.

16. A light emitting device comprising:
a light emitting diode; and
the luminescent glass-ceramic material according to claim 1, covering the light emitting diode.

17. The light emitting device according to claim 16, wherein a wavelength of the light emitting diode is 254 nm to 480 nm.

18. The light emitting device according to claim 16, wherein a shape of the luminescent glass-ceramic material comprises a sheet shape.
